(19) United States
(12) Patent Application Publication
(10) Pub. No.: US 2026/0171987 A1
(43) Pub. Date: Jun. 18, 2026

(54) VOLTAGE COMPARISON CIRCUIT, RELATED INTEGRATED CIRCUIT AND METHOD

(71) Applicant: STMicroelectronics International N.V., Geneva (CH)

(72) Inventors: Mahmoud Savadkouhi, München (DE); Fulvio Schiappelli, Munich (DE)

(21) Appl. No.: 19/420,364

(22) Filed: Dec. 15, 2025

(30) Foreign Application Priority Data
Dec. 18, 2024 (IT) 102024000028974

(51) Int. Cl. H03F 3/45; G01R 15/04; G01R 19/165

(52) U.S. Cl. CPC H03F 3/45094; G01R 19/16519; H03F 3/45174; H03F 3/45475; G01R 15/04

(57) ABSTRACT

According to an embodiment, a voltage comparison circuit comprises terminals for receiving an input voltage and a supply voltage. A measurement circuit generates a measurement signal and comprises first and second resistances coupled in series. An n-channel Field-Effect Transistor is coupled in series with the first resistance, with a gate terminal coupled to a bias voltage source. Collectors of first and second NPN bipolar transistors are coupled to the supply voltage terminal, and bases are coupled to a node between the resistances. A third resistance is coupled between an emitter of the first NPN bipolar transistor and ground, and a fourth resistance is coupled between emitters of the transistors. A comparison circuit determines whether a first current through the first NPN bipolar transistor exceeds a second current through the second NPN bipolar transistor and asserts a comparison signal accordingly. The n-channel Field-Effect Transistor limits the measurement signal.

### CROSS-REFERENCE TO RELATED APPLICATIONS

This application claims the benefit of Italian Patent Application Number 102024000028974, filed on Dec. 18, 2024, which application is hereby incorporated by reference herein in its entirety.

### TECHNICAL FIELD

The embodiments of the present description refer to a voltage comparison circuit.

### BACKGROUND

In many applications, it may be necessary to determine whether a voltage exceeds a given threshold. For example, FIG. 1 shows a typical system in which a circuit 10 comprises two power supply terminals 100 and 102 configured to receive an input voltage VIN. For example, the (negative) terminal 102 may represent ground GND. For example, the circuit 10 may implement a Power Management Unit (PMU). For example, the circuit 10 may implement one or more of the following functions: DC-to-DC conversion, battery charging, power-source selection, voltage scaling, etc.

In the example considered, the circuit 10 includes a detection circuit 12 configured to monitor the input voltage VIN and generate a signal PG indicating whether VIN exceeds a given threshold. For example, FIG. 2 shows the detection circuit 12. Specifically, in the example considered, the detection circuit 12 comprises a measurement circuit 120 configured to generate a measurement signal VS indicative of (e.g., proportional to) the voltage VIN, and a comparison circuit 122 configured to assert or de-assert a comparison signal PG as a function of the signal VS and a threshold signal VTH.

For example, in the example considered, the measurement circuit 120 comprises a voltage divider comprising two resistors RA and RB coupled in series between the terminals 100 and 102, wherein the signal VS corresponds to the voltage at the resistor RB.

In many applications, to indicate the logic level of the signal PG, the comparison signal PG is either set to o V (ground) or a voltage VDD. For example, this may be achieved by supplying the comparison circuit 122 with the voltage VDD. For example, such a detection circuit 12 is disclosed in Chinese Patent CN 101557215 B, which is incorporated herein by reference.

### SUMMARY

Considering the foregoing, it is an object of various embodiments to provide improved solutions for voltage comparison circuits.

According to one or more embodiments, one or more of the above objects are achieved by a voltage comparison circuit having the distinctive elements set forth specifically in the ensuing claims. Embodiments, moreover, concern a related integrated circuit and method.

The scope of protection is defined in the appended claims, which form an integral part of the technical teaching of the description provided herein.

As mentioned before, various embodiments of the present disclosure relate to a voltage comparison circuit configured to assert a comparison signal in response to determining that an input voltage exceeds a given threshold voltage. The voltage comparison circuit, e.g., integrated in an integrated circuit, comprises a first terminal and a second terminal configured to receive the input voltage, and a further terminal configured to receive a supply voltage.

In various embodiments, a measurement circuit is configured to generate a measurement signal indicative of the input voltage, wherein the measurement circuit comprises a first resistance coupled between the first terminal and a first node, and a second resistance coupled between the first node and the second terminal, wherein the measurement signal corresponds to the voltage at the second resistance.

In various embodiments, the collectors of a first NPN bipolar transistor and a second NPN bipolar transistor are coupled to the further terminal configured to receive a supply voltage, and the bases of the first NPN bipolar transistor and the second NPN bipolar transistor are coupled to the first node. Specifically, the emitter area of the second bipolar transistor is greater than the emitter area of the first bipolar transistor. A third resistance is coupled between the emitter of the first NPN bipolar transistor and the second terminal, and a fourth resistance is coupled between the emitter of the second NPN bipolar transistor and the emitter of the first NPN bipolar transistor.

In various embodiments, a comparison circuit is configured to determine whether a first current flowing through the collector of the first NPN bipolar transistor is greater than a second current flowing through the collector of the second NPN bipolar transistor. In response to determining that the first current is greater than the second current, the comparison circuit asserts the comparison signal. Conversely, in response to determining that the first current is smaller than the second current, the comparison circuit de-asserts the comparison signal.

According to a first aspect of the present disclosure, the measurement circuit comprises an n-channel Field-Effect Transistor, wherein the n-channel Field-Effect Transistor and the first resistance are coupled in series between the first terminal and the first node, wherein the gate terminal of the n-channel Field-Effect Transistor is coupled to a bias voltage source. In various embodiments, the gate terminal of the n-channel Field-Effect Transistor is coupled to the further terminal configured to receive a supply voltage.

For example, in various embodiments, a drain of the n-channel Field-Effect Transistor is coupled to the first terminal, and a source of the n-channel Field-Effect Transistor is coupled via the first resistance to the first node. Alternatively, a source of the n-channel Field-Effect Transistor is coupled to the first node, and the drain of the n-channel Field-Effect Transistor is coupled via the first resistance to the first terminal.

In various embodiments, the voltage comparison circuit includes hysteresis. For this purpose, the second resistance may be a resistance switchable between a first resistance value and a second resistance value as a function of the comparison signal. For example, for this purpose, the second resistance may comprise two resistances coupled in series between the first node and the second terminal, and an electronic switch configured to short-circuit one of the two resistances when the comparison signal is de-asserted.

According to a second aspect of the present disclosure, the comparison circuit comprises a first transistor of a first current mirror connected between the collector of the first NPN bipolar transistor and the further terminal configured to receive a supply voltage. A second transistor of the first current mirror is coupled between the collector of the second NPN bipolar transistor and the further terminal configured to receive a supply voltage. Moreover, a third transistor and a pull-down resistance are coupled between the further terminal configured to receive a supply voltage and the second terminal, wherein a control terminal of the third transistor is coupled to the collector of the first NPN bipolar transistor. In this case, the comparison signal may be determined as a function of the voltage at the pull-down resistance.

According to a third aspect of the present disclosure, the comparison circuit comprises a fifth resistance coupled between the collector of the first NPN bipolar transistor and the further terminal configured to receive a supply voltage and a sixth resistance coupled between the collector of the second NPN bipolar transistor and the further terminal configured to receive a supply voltage. An operational amplifier has a first input coupled to the collector of the first NPN bipolar transistor and a second input coupled to the collector of the second NPN bipolar transistor. In this case, the comparison signal is determined as a function of the voltage at and output of the operation amplifier.

For example, in various embodiments, the operation amplifier comprises a fourth transistor and a fifth transistor, such as p-channel FETs, wherein control terminals of the fourth transistor and the fifth transistor are coupled to the collectors of the first NPN bipolar transistor and the second NPN bipolar transistor, respectively. A second current mirror may comprise a sixth transistor coupled to the current path of the fourth transistor between the further terminal configured to receive a supply voltage and the second terminal, and a seventh transistor coupled to the current path of the fifth transistor between the further terminal configured to receive a supply voltage and the second terminal. Moreover, an eighth transistor and a pull-up resistance may be coupled between the further terminal configured to receive a supply voltage and the second terminal, wherein a control terminal of the eighth transistor is coupled to an intermediate node between the sixth transistor and the fourth transistor. In this case, the comparison signal may be determined as a function of the voltage at the intermediate node.

In various embodiments, the fifth and sixth resistances (and similarly the other resistances) may be implemented using respective FETs configured to receive a bias voltage at their respective gate terminals.

### BRIEF DESCRIPTION OF THE DRAWINGS

The embodiments of the present disclosure will now be described with reference to the annexed plates of drawings, which are provided purely to way of non-limiting example and in which:

The features and advantages of the present invention will become apparent from the following detailed description of practical embodiments thereof, shown by way of non-limiting example in the accompanying drawings, in which:

FIG. 1 shows an electronic system comprising a voltage comparison circuit

FIG. 2 shows a voltage comparison circuit;

FIG. 3 shows a voltage measurement circuit;

FIG. 4 shows a voltage comparison circuit;

FIG. 5 shows waveforms of currents flowing in the voltage comparison circuit of FIG. 4; and

FIGS. 6, 7, 8, 9, 10, 11, and 12 show voltage comparison circuits.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

In the ensuing description, various specific details are illustrated, aimed at enabling an in-depth understanding of the embodiments. The embodiments may be provided without one or more of the specific details, or with other methods, components, materials, etc. In other cases, known structures, materials, or operations are not shown or described in detail so that various aspects of the embodiments will not be obscured.

Reference to “an embodiment” or “one embodiment” in the framework of this description is meant to indicate that a particular configuration, structure, or characteristic described in relation to the embodiment is comprised in at least one embodiment. Hence, phrases such as “in an embodiment,” “in one embodiment,” or the like that may be present in various points of this description do not necessarily refer to the same embodiment. Moreover, particular conformations, structures, or characteristics may be combined in any adequate way in one or more embodiments.

The references used herein are only provided for convenience and hence do not define the sphere of protection or the scope of the embodiments.

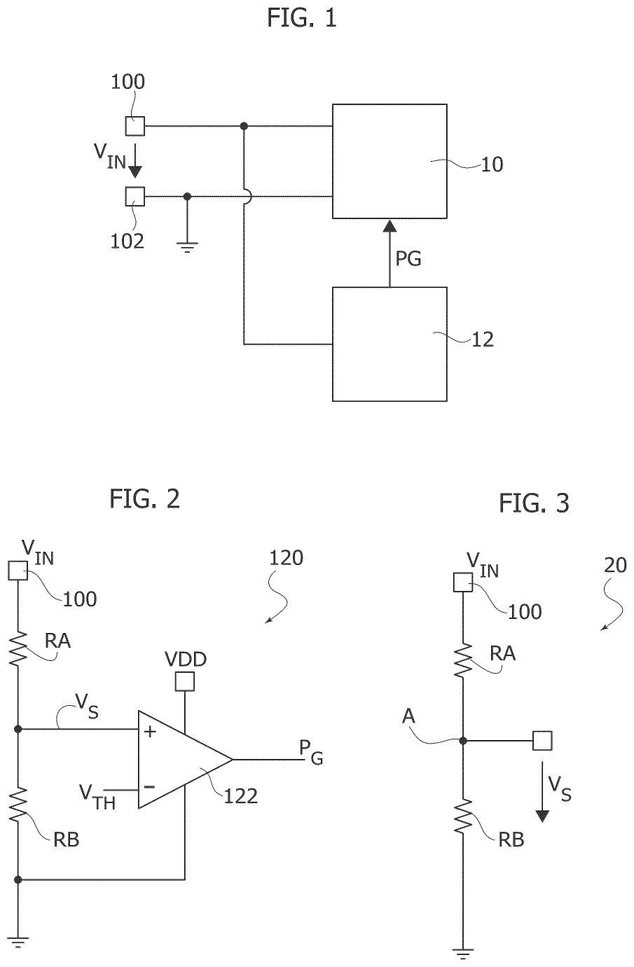

In FIGS. 3 to 12 described below, parts, elements or components that have already been described with reference to FIGS. 1 and 2 are designated by the same references used previously in these figures. The description of these elements has already been made and will not be repeated in what follows in order not to burden the present detailed description.

As mentioned before, various embodiments of the present disclosure relate to a detection circuit configured to assert a comparison signal PG in response to determining that a voltage VIN is greater than a given threshold.

FIG. 3 shows an embodiment of a measurement circuit 20 configured to generate a signal VS indicative of a voltage VIN. For example, similar to the circuit shown in FIG. 2, in the embodiment considered, the measurement circuit 20 comprises a voltage divider comprising (at least) a first resistance RA and a secondo resistance RB coupled in series between the voltage VIN and ground, wherein the measurement signal VS corresponds to the voltage at the resistance RB, i.e., the voltage at an intermediate node A of the voltage divider. For example, in the embodiment considered, a first terminal of the resistance RA is coupled to the terminal 100, a second terminal of the resistance RA is coupled to a first terminal of the resistance RB (representing the node A), and a second terminal of the resistance RB is coupled to the terminal 102/ground.

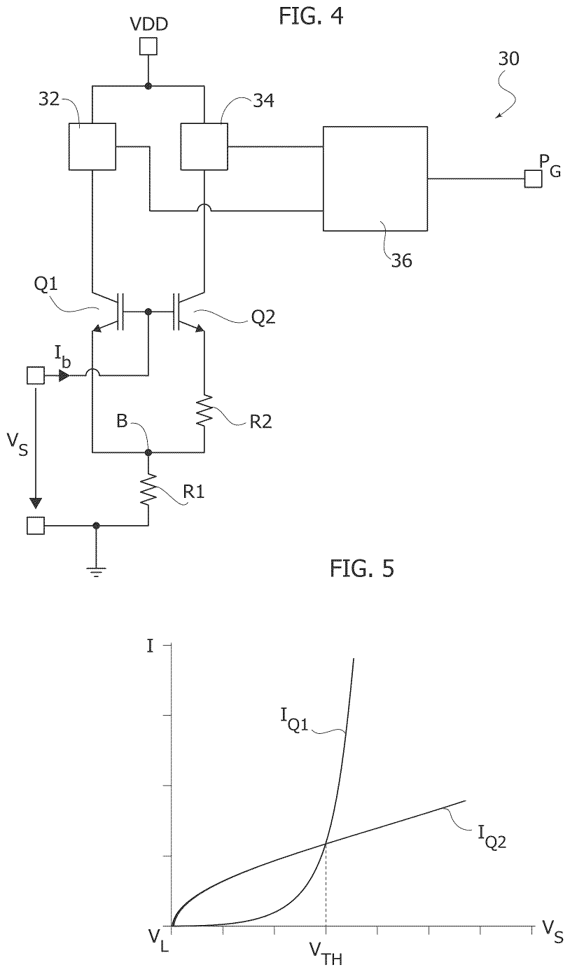

FIG. 4 shows an embodiment of a comparison circuit 30. Substantially, in the embodiment considered, the comparison circuit 30 is implemented around a Brokaw bandgap reference. For example, in this context, the article by Paul Brokaw, “A Simple Three-Terminal IC Bandgap Reference,” IEEE Journal of Solid-State Circuits, Vol. SC-9, No. 6, December 1974, PP 388-393, which is incorporated herein by reference.

Specifically, in the embodiment considered, the comparison circuit 30 comprises a first NPN bipolar transistor Q1 and a second NPN bipolar transistor Q2. In the embodiment considered, the emitter of transistor Q1 is coupled (e.g., directly) to node B, and its collector is coupled to the supply voltage VDD. Moreover, in the embodiment considered, the emitter of transistor Q2 is coupled (e.g., directly) via resistor R2 to node B, and the collector of transistor Q2 is coupled to the supply voltage VDD. In the embodiment considered, node B is coupled (e.g., directly) to ground via a resistor. Specifically, as explained below, the term “connect” does not imply that the collector terminals are directly connected to the voltage VDD.

Specifically, in the embodiment considered, the base terminal of the transistor Q1 is coupled (e.g., directly) to the base terminal of the transistor Q2, wherein the base terminals receive the measurement voltage VS.

Specifically, in various embodiments, the emitter area of transistor Q2 is N times that of transistor Q1. For example, in various embodiments, N is greater than four. Thus, the larger transistor Q2 will achieve a given current at a lower base-emitter voltage VBE than the smaller transistor Q1. Accordingly, since the transistor Q2 has an emitter area that is N times larger than the emitter area of the transistor Q1, the base-emitter voltage VBE2 of the transistor Q2 will be lower than the base-emitter voltage VBE1 of the transistor Q1 by a magnitude of:

$${ΔV}_{BE} = {V}_{T} ln ( N ) \qquad ( 1 )$$

where VT corresponds to the thermal voltage (kT/q). For example, in various embodiments, N equals 8 because ln(N) is approximately 2.

Specifically, as shown in FIG. 5, once the voltage VS exceeds the lower threshold VL, transistors Q1 and Q2 are conductive. Specifically, when the voltage VS is below a threshold voltage VTH, the current IQ1 through transistor Q1 is lower than the current IQ2 through transistor Q2 (due to the lower base-emitter voltage). Conversely, when the voltage VS is greater than the threshold voltage VTH, the current IQ1 flowing through the transistor Q1 is greater than the current IQ2 flowing through the transistor Q2.

Specifically, the threshold voltage VTH corresponds to the point at which the currents IQ1 and IQ2 are equal, i.e., IQ1=IQ2. In this situation, the voltage difference AVBE is applied to the resistor R2, and the resistor R1 is transversed by a current corresponding to 2·IQ2, i.e., the following voltage V1 is generated at the resistor R1:

$${V}_{1} = 2 \frac{R 1}{R 2} {V}_{T} ln ( N ) \qquad ( 2 )$$

Thus, the threshold voltage VTH corresponds to the sum of the voltage drop V1 and the base-emitter voltage VBE1 of the transistor Q1, i.e.:

$${V}_{TH} = {V}_{1} + {V}_{BE 1} = 2 \frac{R 1}{R 2} {V}_{T} ln ( N ) + {V}_{BE 1} \qquad ( 3 )$$

Specifically, according to a Brokaw bandgap reference, the threshold VTH is substantially constant over temperature.

Accordingly, by also taking into account the voltage divider RA and RB, the threshold voltage VIN_TH for the input voltage VIN may be calculated as:

$${V}_{IN \_ TH} = ( 1 + \frac{RA}{RB} ) {V}_{TH} = ( 1 + \frac{RA}{RB} ) ( 2 \frac{R 1}{R 2} {V}_{T} ln ( N ) + {V}_{BE 1} ) \qquad ( 4 )$$

Accordingly, in the embodiments considered, the circuit is configured to compare the collector current IQ1 of the transistor Q1 with the collector current IQ2 of the transistor Q2. For example, in the embodiment considered, the collector of the transistor Q1 is coupled (e.g., directly) via a first current measurement circuit 32 to the voltage VDD, and the collector of the transistor Q2 is coupled (e.g., directly) via a second current measurement circuit 34 to the voltage VDD. Moreover, a comparison circuit 36 is configured to generate the signal PG as a function of the signals provided by the current measurement circuits 32 and 34.

Accordingly, in the embodiment considered, the measurement voltage VS is applied directly to the base terminals of the transistors Q1 and Q2. Specifically, the use of the voltage dividers RA and RB within the measurement circuit 20 permits monitoring of voltages VIN that are greater than the voltage VDD. Accordingly, the comparison circuit 30 may be in a low-voltage domain. For example, the voltage VDD may be selected within a range of 1-5 V, e.g., 2.5-3 V. The voltage VIN (when supplied to the terminals 100 and 102) may be greater than the voltage VDD, e.g., VIN may be greater than 5 V, e.g., between 9 V and 24 V. A low-voltage comparison circuit 30 also has several advantages. First of all, the comparison circuit 30 already provides a binary comparison signal PG in the low-voltage domain, which is usually used by other digital processing circuits, e.g., within the circuit 10, thereby avoiding an additional level shifter circuit. Moreover, low-voltage components, such as transistors and resistors, usually exhibit better matching and accuracy, e.g., with respect to process, voltage, and temperature (PVT) variations. Furthermore, the area of low-voltage components is usually smaller than that of the corresponding high-voltage components.

However, if the input voltage VIN varies, the measurement voltage VS may exceed VDD, potentially damaging the circuit 30. Thus, the measurement voltage VS should be limited to VDD or less. For example, this may be obtained by limiting the voltage VS via a Zener diode. However, such a Zener diode will generate electrical losses depending on the current flowing through the resistance RA. Thus, to reduce the power consumption of the detection circuit 20, the resistances RA and RB should be large.

However, as shown in FIG. 4, indeed a given base current Ib will flow through the base of the transistors Q1 and Q2, which generates an additional voltage drop at the resistance RA, i.e., the actual threshold voltage corresponds to:

$${V}_{IN \_ TH} = ( 1 + \frac{RA}{RB} ) ( 2 \frac{R 1}{R 2} {V}_{T} ln ( N ) + {V}_{BE 1} ) + RA \cdot {I}_{b} \qquad ( 5 )$$

where the term EIB=RA·Ib corresponds to an error.

However, this implies that the EIB error also increases as RA increases. Thus, in the following, solutions will be described that limit current consumption for high VIN voltages while improving the accuracy of the threshold VIN_TH by minimizing the error EIB.

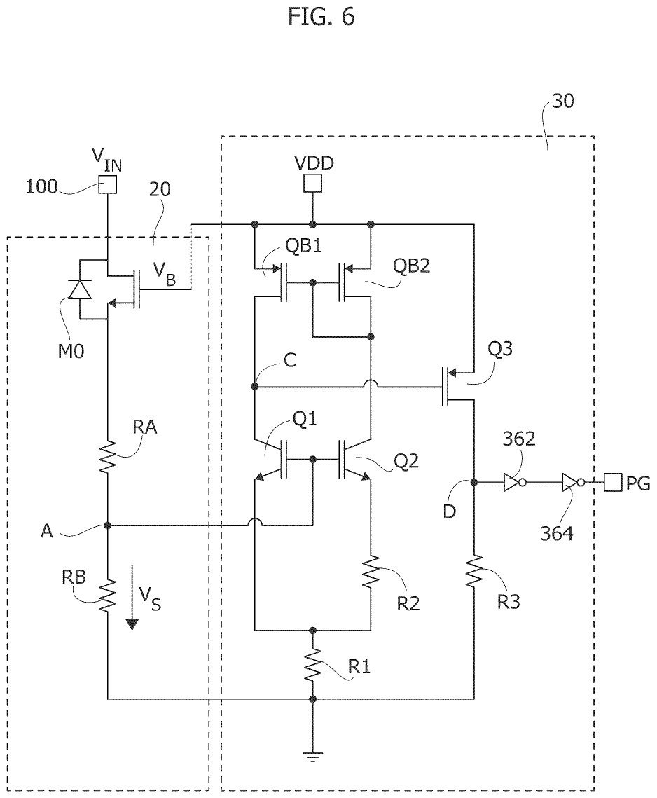

FIG. 6 shows an embodiment of a voltage comparison circuit according to the present disclosure. Specifically, in the embodiment considered, the measurement circuit 20 comprises now a clamping circuit implemented with an n-channel Field-Effect Transistor (FET) Mo.

Specifically, in the embodiment considered, the current path of the FET Mo is coupled (e.g., directly) between the resistance RA and the terminal 100 configured to receive the voltage VIN. Specifically, in the embodiment considered, the drain terminal of the FET Mo is coupled (e.g., directly) to the terminal 100, and the source terminal of the FET Mo is coupled (e.g., directly) via the voltage divider RA and RB to ground, i.e., the terminal 102. Specifically, in the embodiment considered, a first terminal of the resistance RA is coupled to the source terminal of the FET Mo, a second terminal of the resistance RA is coupled to a first terminal of the resistance RB and a second terminal of the resistance RB is coupled to the terminal 102, wherein the intermediate node A between the resistances RA and RB is coupled to the base terminals of the transistors Q1 and Q2.

Specifically, in various embodiments, the gate terminal of the FET Mo is coupled to a bias voltage VB indicative of a maximum value to which the voltage at the source terminal of the FET Mo should be limited. For example, in the embodiment considered, the gate terminal is coupled (e.g., directly) to the voltage VDD, i.e., VB=VDD.

Accordingly, in the embodiment considered, when the voltage VIN is smaller than a threshold value corresponding to VB-VT, where VT corresponds to the threshold voltage of the FET Mo, the FET Mo is in the triode region, i.e., the voltage at the source terminal of the FET Mo corresponds approximately to VIN. Conversely, when the voltage VIN is greater than VB-VT, the FET Mo is in saturation, i.e., the voltage at its source terminal is approximately VB-VT.

Accordingly, in the embodiment considered, the clamping circuit Mo limits the current through the voltage divider RA, RB when VIN>VB−VT. Thus, the values of the resistances RA and RB may be smaller, thereby reducing also the error EIB.

FIG. 6 also shows an embodiment of the circuit 30. Specifically, in the embodiment considered, the current measurement circuits 32 and 34 are implemented with an active load. Specifically, in the embodiment considered, the circuit 30 comprises first p-channel FET QB1, wherein the source terminal of the FET QB1 is coupled (e.g., directly) to the voltage VDD, and the drain terminal of the FET QB1 is coupled (e.g., directly) to the collector terminal of the transistor Q1, which represents a node C. Similarly, in the embodiment considered, the circuit 30 comprises second p-channel FET QB2, wherein the source terminal of the FET QB2 is coupled (e.g., directly) to the voltage VDD, and the drain terminal of the FET QB2 is coupled (e.g., directly) to the collector terminal of the transistor Q2. Specifically, in the embodiment considered, the gate terminal of the FET QB1 is coupled (e.g., directly) to the gate terminal of the FET QB2, which is coupled (e.g., directly) to the drain terminal of the FET QB2. Accordingly, in the embodiment considered, the FETs QB1 and QB2 implement essentially a current mirror.

Thus, once the current IQ1 exceeds the current IQ2, the voltage at the node C/collector of the transistor Q1 decreases. Accordingly, in the embodiment considered, the comparison circuit 36 is configured to generate the comparison signal PG as a function of the voltage at the node C. For example, in the embodiment considered, the comparison circuit 36 comprises a p-channel FET Q3, having a source terminal coupled (e.g., directly) to the voltage VDD, a drain terminal coupled to a node D, and a gate terminal coupled to the node C, whereby the transistor Q3 is closed when the current IQ1 exceeds the current IQ2. In various embodiments, the node D is coupled via a pull-down resistance R3 to ground.

In various embodiments, the p-channel FETs QB1, QB2 and Q3 may also be replaced with respective pnp bipolar transistors, wherein the source terminal of a FET is replaced with the emitter terminal of a respective bipolar transistor, the drain terminal of a FET is replaced with the collector terminal of a respective bipolar transistor, and the gate terminal of a FET is replaced with the base terminal of a respective bipolar transistor.

Accordingly, in the embodiment considered, the voltage at node B is high when the current IQ1 exceeds the current IQ2. Accordingly, the signal PG may correspond to the voltage at the node B, i.e., the voltage at the resistance R3, or an even number of logic inverters (supplied by the voltage VDD) may be used to generate the signal PG as a function of the voltage at the node B. For example, in the embodiment considered, two inverters 362 and 364 are coupled in cascade between the node B and the terminal providing the signal PG.

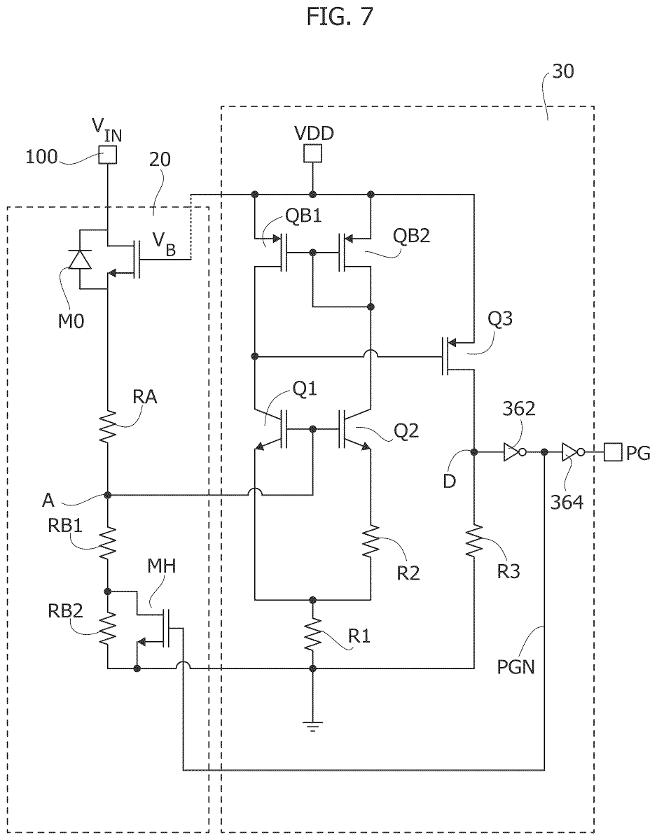

FIG. 7 shows an embodiment of a voltage comparison circuit with hysteresis. Specifically, in the embodiment considered, the resistance RB is switchable between two resistance values. For example, in the embodiment considered, the resistance RB comprises two resistances RB1 and RB2 coupled in series between the node A and ground. Moreover, an electronic switch MH is used to selectively short-circuit the resistance RB2. For example, in the embodiment considered, the resistance RB2 is coupled to ground. For example, the electronic switch MH may be an n-channel FET. For example, in the embodiment considered, the source terminal of the FET MH is coupled to ground, and its drain terminal is coupled to the intermediate node between the resistances RB1 and RB2.

Accordingly, when the electronic switch MH is closed, the detection circuit has the following (rising) threshold for the input voltage VIN:

$${V}_{IN \_ TH \_ H} = ( 1 + \frac{RA}{RB 1} ) ( 2 \frac{R 1}{R 2} {V}_{T} ln ( N ) + {V}_{BE 1} ) + RA \cdot {I}_{b} \qquad ( 6 )$$

Conversely, when the electronic switch MH is opened, the detection circuit has the following (falling) threshold for the input voltage VIN:

$${V}_{IN \_ TH \_ L} = ( 1 + \frac{RA}{RB 1 + RB 2} ) ( 2 \frac{R 1}{R 2} {V}_{T} ln ( N ) + {V}_{BE 1} ) + RA \cdot {I}_{b} \qquad ( 7 )$$

Accordingly, to implement a comparator with hysteresis, the electronic switch MH may initially be closed, thereby setting the threshold voltage VTH to the voltage VIN_TH_H. Next, once the signal PG is asserted, the electronic switch MH opens, thereby setting the threshold voltage VTH to VIN_TH_L. Accordingly, in various embodiments, the electronic switch MH may be configured to short-circuit the resistance RB2 in response to determining that the signal PG is low/de-asserted. For example, in the embodiment considered, the gate terminal of the FET MH is coupled to the output of the inverter 362 and receives thus an inverted version PGN of the signal PG.

The use of a switchable voltage divider also has the advantage that the current consumption of the measurement circuit 20 is decreased once the signal PG is asserted.

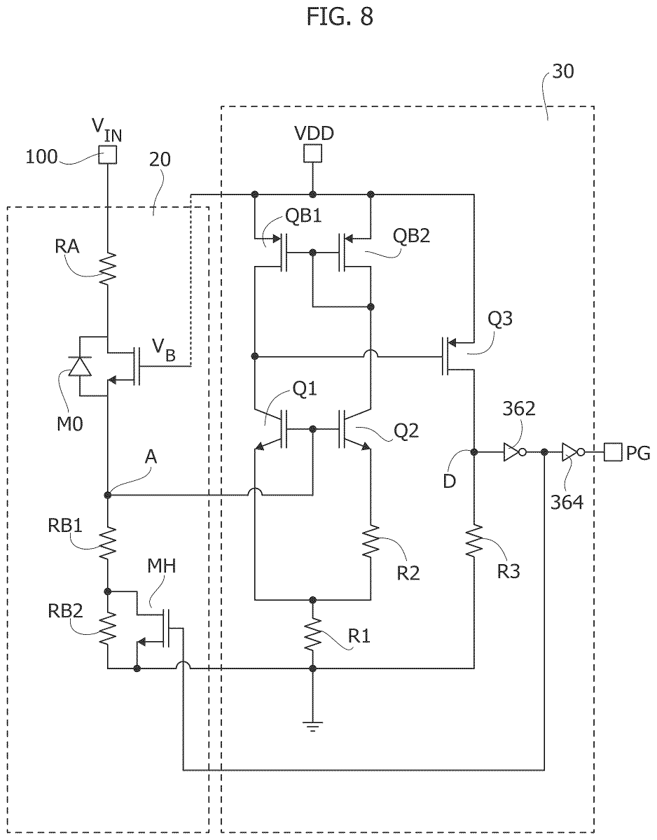

FIG. 8 shows an alternative embodiment of the measurement circuit 20, wherein the clamping FET Mo is not coupled between the voltage VIN and voltage divider RA, RB, but between the resistance RA and the node A, i.e., a first terminal of the resistance RA is coupled (e.g., directly) to the terminal 100 and a second terminal of the resistance RA is coupled (e.g., directly) to the drain terminal of the FET Mo, the source terminal of the FET Mo is coupled (e.g., directly) to the node A, and the gate terminal of the FET Mo is coupled to the bias voltage VB, e.g., VDD. Accordingly, in the embodiment considered, the voltage VS is clamped/limited to the voltage VB-VT.

In various embodiments, the measurement circuit 20 may also comprise a switchable resistance RB, e.g., implemented with the resistances RB1 and RB2, and the electronic switch MH.

Accordingly, the solution shown in FIG. 8 permits direct limitation of the voltage VS, which permits selecting the threshold voltage VTH of the circuit 30 in a wider range. However, the solution shown in FIG. 8 has higher current consumption because the voltage VS may be higher, thereby generating a higher current through the resistance RB (or equivalently RB1+RB2).

In the following, further alternative embodiments of the current measurement circuits 32 and 34, and the comparison circuit 36 will be described. In general, these circuits may be used with any of the measurement circuits 20 shown in FIGS. 3, 6, 7, and 8. For example, without loss of generality, the measurement circuit 20 shown in FIG. 7 will be used in the embodiments considered.

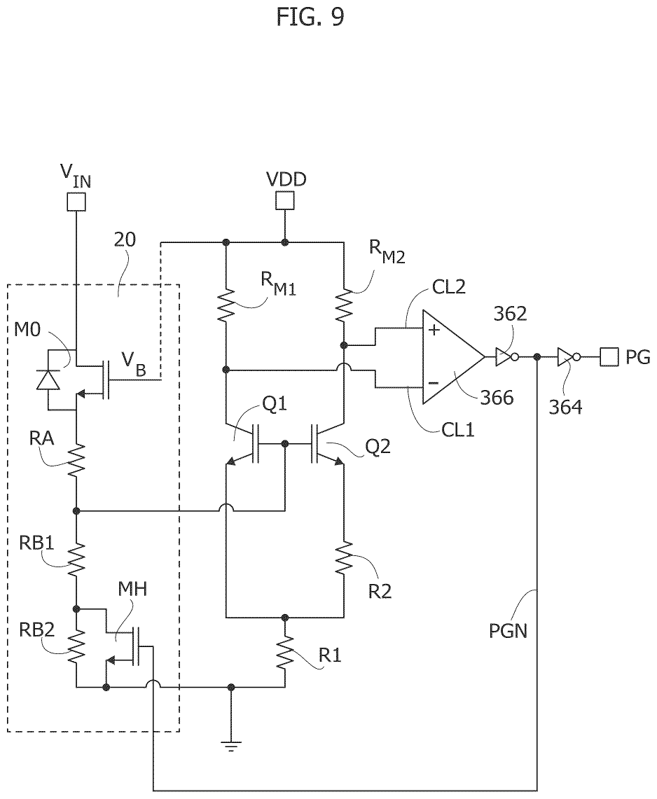

FIG. 9 shows an embodiment, wherein the current measurement circuits 32 and 34 are implemented with resistances RM1 and RM2, i.e., the collector of the transistor Q1 is coupled (e.g., directly) via the resistance RM1 to the voltage VDD, and the collector of the transistor Q2 is coupled (e.g., directly) via the resistance RM2 to the voltage VDD. Specifically, in various embodiments, the resistances RM1 and RM2 are equal.

Accordingly, in the embodiment considered, the voltage at the resistance RM1 is proportional to the current IQ1, and the voltage at the resistance RM2 is proportional to the current IQ2. Accordingly, in the embodiment considered, the voltages CL1 and CL2 at the collector terminals of the transistors Q1 and Q2, respectively, are provided to a comparator/operational amplifier 366, i.e., a first input terminal, e.g. the negative/inverting input terminal, of the operational amplifier 366 is coupled (e.g., directly) to the collector of the transistor Q2, and a second input terminal, e.g. the positive/non-inverting input terminal, of the operational amplifier 366 is coupled (e.g., directly) to the collector of the transistor Q2. Accordingly, based on the connection to the input terminals of the operational amplifier 366, the output of the operational amplifier 366 may provide the signal PG or PGN.

For example, in the embodiment considered, the operational amplifier output is high when the voltage CL1 at transistor Q1 is lower than the voltage CL2 at transistor Q2, indicating that the current IQ1 is greater than the current IQ2. Accordingly, in this case, the signal PG may correspond to the signal at the output of the operational amplifier 366, or an even number of inverters, e.g., two inverters 362 and 364, may generate the signal PG as a function of that signal.

For example, using inverters 362 and 364, the PGN signal used by the electronic switch MH may correspond to the output of inverter 362.

However, by inverting the input terminal of the operational amplifier 366, the signal at the output of the operational amplifier 366 may correspond to the signal PGN, and the inverter 362 may be omitted.

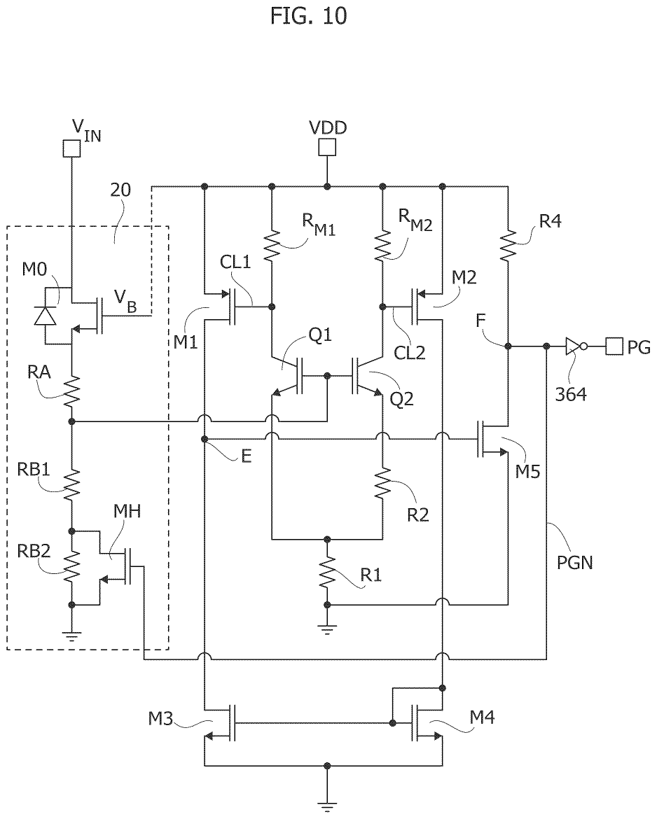

FIG. 10 shows an embodiment of the operational amplifier 366. Specifically, in the embodiment considered, the collector of the transistor Q1 is coupled (e.g., directly) to the gate of a first p-channel FET M1, i.e., the gate of the FET M1 receives the voltage CL1, and the collector of the transistor Q2 is coupled (e.g., directly) to the gate of a second p-channel FET M2, i.e., the gate of the FET M2 receives the voltage CL2.

Moreover, in the embodiment considered, the source terminals of the FETs M1 and M2 are coupled (e.g., directly) to the voltage VDD and the drain terminals of the FETs M1 and M2 are coupled to a current mirror comprising two n-channel FETs M3 and M4. Specifically, in the embodiment considered, the drain terminal of the FET M3 is coupled (e.g., directly) to the drain terminal of the FET M1, the source terminal of the FET M3 is coupled (e.g., directly) to ground, the drain terminal of the FET M4 is coupled (e.g., directly) to the drain terminal of the FET M2, and the source terminal of the FET M4 is coupled (e.g., directly) to ground. Moreover, the gate terminal of the FET M3 is coupled (e.g., directly) to the gate terminal of the FET M4, which is coupled (e.g., directly) to the drain terminal of the FET M4.

Accordingly, as described with respect to FIG. 6, in the embodiment considered, the transistors M3 and M4 act as current sensors. Accordingly, in the embodiment considered, the circuit 30 may be configured to generate the signal PG as a function of the voltage at the drain terminal of the FET M3, which is also indicated as node E. For example, in the embodiment considered, the voltage at the drain terminal of the FET M3 drives the gate of the n-channel FET M5; i.e., the gate of the FET M5 is coupled to the node E. Specifically, the FET M5 is coupled between the node F and ground. In this case, a pull-up resistance R4 may be coupled between the node F and the voltage VDD. Accordingly, in the embodiment considered, when the current IQ1 is greater than the current IQ2, the voltage CL1 is lower than the voltage CL2, thereby closing the FET M5. Accordingly, in the embodiment considered, the signal PGN may correspond to the voltage at the node F, and an additional inverter 364 may be used to generate the signal PG as a function of the voltage at the node F.

In various embodiments, the gate terminal of the transistor M1 may alternatively be coupled to the collector of the transistor Q2, and the gate terminal of the transistor M2 may be coupled to the collector of the transistor Q1. In this case, the voltage at node F exhibits the opposite behavior, and an additional inverter 362 may be used to generate the PGN signal as a function of the voltage at node F.

Moreover, similar to the discussion of FIG. 6, the FETs M3, M4 and M5 may be replaced with respective bipolar transistors, wherein the source terminal of a FET is replaced with the emitter terminal of a respective bipolar transistor, the drain terminal of a FET is replaced with the collector terminal of a respective bipolar transistor, and the gate terminal of a FET is replaced with the base terminal of a respective bipolar transistor.

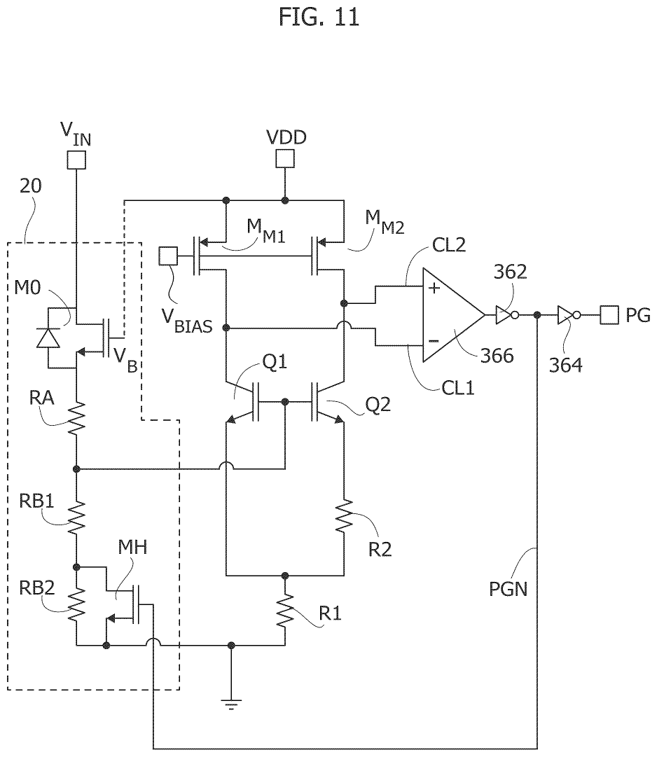

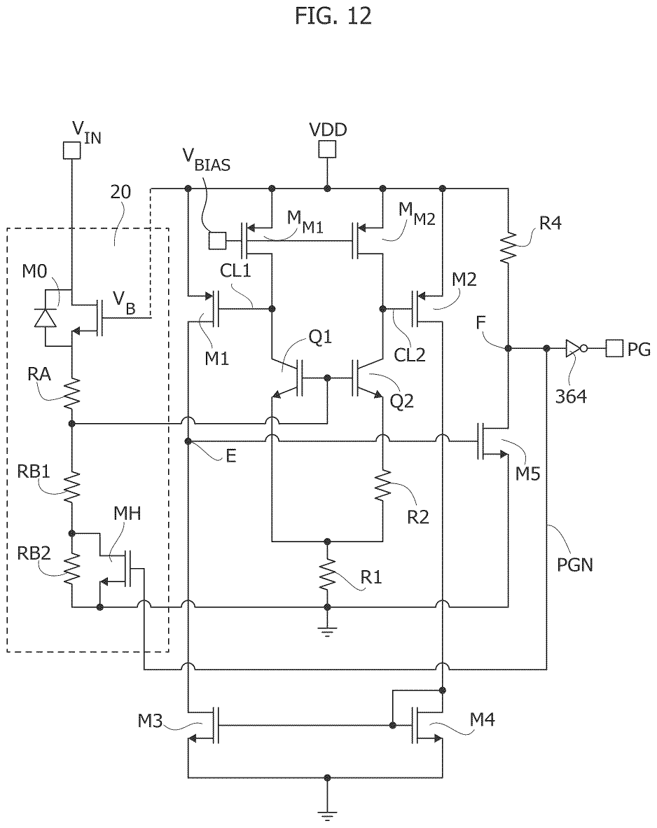

FIGS. 11 and 12 represent alternative embodiments, wherein the resistances RM1 and RM2 of FIGS. 9 and 11 have been replaced with p-channel FETs MM1 and MM2.

Specifically, in the embodiments considered, the collector of the transistor Q1 is coupled (e.g., directly) to the drain of the FET MM1, and the source of the FET MM1 is coupled (e.g., directly) to the supply voltage VDD. Similarly, the collector of the transistor Q2 is coupled (e.g., directly) to the drain of the FET MM2, and the source of the FET MM2 is coupled (e.g., directly) to the supply voltage VDD. Moreover, the gate terminals of the FETS MM1 and MM2 are coupled to a bias voltage VBIAS. To implement the same resistance (for a given bias voltage), the MM1 and MM2 have the same characteristics. Moreover, in various embodiments, the MM1 and MM2 are not diode-connected.

For the rest, the circuits shown in FIGS. 11 and 12 operate as the embodiments discussed with respect to FIGS. 9 and 10, and the respective description applies in its entirety.

Accordingly, the various resistances shown in FIGS. 3 to 12 may be implemented with discrete resistors or via resistances, in the integrated circuit of the detection circuit (e.g., tracks of given length), or, as shown in FIGS. 11 and 12, by replacing the resistances with suitably biased FETs.

Of course, without prejudice to the principle of the invention, the details of construction and the embodiments may vary widely with respect to what has been described and illustrated herein purely by way of example, without thereby departing from the scope of the present invention, as defined by the ensuing claims.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A voltage comparison circuit configured to assert a comparison signal in response to determining that an input voltage exceeds a given threshold voltage, the voltage comparison circuit comprising:
a first terminal and a second terminal configured to receive the input voltage;
a third terminal configured to receive a supply voltage;
a measurement circuit configured to generate a measurement signal indicative of the input voltage, wherein the measurement circuit comprises a first resistance coupled between the first terminal and a first node, and a second resistance coupled between the first node and the second terminal, wherein the measurement signal corresponds to a voltage at the second resistance;
a first NPN bipolar transistor and a second NPN bipolar transistor, each having a collector terminal, an emitter terminal, and a base terminal, wherein the collector terminals of the first NPN bipolar transistor and the second NPN bipolar transistor are coupled to the third terminal, and the base terminals of the first NPN bipolar transistor and the second NPN bipolar transistor are coupled to the first node, wherein an emitter area of the second NPN bipolar transistor is greater than an emitter area of the first NPN bipolar transistor;
a third resistance coupled between the emitter terminal of the first NPN bipolar transistor and the second terminal, and a fourth resistance coupled between the emitter terminal of the second NPN bipolar transistor and the emitter terminal of the first NPN bipolar transistor; and
a comparison circuit configured to:
determine whether a first current flowing through the collector terminal of the first NPN bipolar transistor is greater than a second current flowing through the collector terminal of the second NPN bipolar transistor,
assert the comparison signal in response to determining that the first current is greater than the second current, and
de-assert the comparison signal in response to determining that the first current is smaller than the second current,
wherein the measurement circuit comprises an n-channel Field-Effect Transistor (FET), wherein the n-channel FET and the first resistance are coupled in series between the first terminal and the first node, wherein a gate terminal of the n-channel FET is coupled to a bias voltage source.

2. The voltage comparison circuit of claim 1, wherein the gate terminal of the n-channel FET is coupled to the third terminal.

3. The voltage comparison circuit of claim 1, wherein a drain terminal of the n-channel FET is coupled to the first terminal and a source terminal of the n-channel FET is coupled via the first resistance to the first node.

4. The voltage comparison circuit of claim 1, wherein a source terminal of the n-channel FET is coupled to the first node and a drain terminal of the n-channel FET is coupled via the first resistance to the first terminal.

5. The voltage comparison circuit of claim 1, wherein the second resistance is switchable between a first resistance value and a second resistance value as a function of the comparison signal.

6. The voltage comparison circuit of claim 5, wherein the second resistance comprises two resistances coupled in series between the first node and the second terminal, and an electronic switch configured to short-circuit one of the two resistances when the comparison signal is de-asserted.

7. The voltage comparison circuit of claim 1, wherein the comparison circuit comprises:
a first transistor of a first current mirror coupled between the collector terminal of the first NPN bipolar transistor and the third terminal;
a second transistor of the first current mirror coupled between the collector terminal of the second NPN bipolar transistor and the third terminal; and
a third transistor and a pull-down resistance coupled between the third terminal and the second terminal, wherein a control terminal of the third transistor is coupled to the collector terminal of the first NPN bipolar transistor,
wherein the comparison signal is determined as a function of a voltage at a node between the third transistor and the pull-down resistance.

8. The voltage comparison circuit of claim 1, wherein the comparison circuit comprises:
a fifth resistance coupled between the collector terminal of the first NPN bipolar transistor and the third terminal;
a sixth resistance coupled between the collector terminal of the second NPN bipolar transistor and the third terminal; and
an operational amplifier having a first input coupled to the collector terminal of the first NPN bipolar transistor and a second input coupled to the collector terminal of the second NPN bipolar transistor,
wherein the comparison signal is determined as a function of a voltage at an output of the operational amplifier.

9. The voltage comparison circuit of claim 8, wherein the operational amplifier comprises:
a fourth transistor and a fifth transistor, wherein control terminals of the fourth transistor and the fifth transistor are coupled to the collector terminals of the first NPN bipolar transistor and the second NPN bipolar transistor, respectively;
a second current mirror comprising a sixth transistor coupled with a current-path of the fourth transistor between the third terminal and the second terminal, and a seventh transistor coupled with a current-path of the fifth transistor between the third terminal and the second terminal; and
an eighth transistor and a pull-up resistance coupled between the third terminal and the second terminal, wherein a control terminal of the eighth transistor is coupled to an intermediate node between the sixth transistor and the fourth transistor,
wherein the comparison signal is determined as a function of a voltage at a node between the eighth transistor and the pull-up resistance.

10. The voltage comparison circuit of claim 8, wherein the fifth resistance and the sixth resistance comprise respective p-channel Field-Effect Transistors configured to receive a bias voltage at respective gate terminals.

11. A method of operating a voltage comparison circuit, the method comprising:
receiving an input voltage at a first terminal and a second terminal;
receiving a supply voltage at a third terminal;
generating a measurement signal indicative of the input voltage via a measurement circuit, wherein the measurement circuit comprises a first resistance coupled between the first terminal and a first node, and a second resistance coupled between the first node and the second terminal;
applying the measurement signal to base terminals of a first NPN bipolar transistor and a second NPN bipolar transistor;
determining, via a comparison circuit, whether a first current flowing through a collector terminal of the first NPN bipolar transistor is greater than a second current flowing through a collector terminal of the second NPN bipolar transistor;
asserting a comparison signal in response to determining that the first current is greater than the second current;
de-asserting the comparison signal in response to determining that the first current is smaller than the second current; and
limiting the measurement signal by using an n-channel Field-Effect Transistor (FET) coupled in series with the first resistance between the first terminal and the first node.

12. The method of claim 11, wherein a gate terminal of the n-channel FET is coupled to the third terminal.

13. The method of claim 11, wherein limiting the measurement signal comprises:
coupling a drain terminal of the n-channel FET to the first terminal; and
coupling a source terminal of the n-channel FET via the first resistance to the first node.

14. The method of claim 11, further comprising switching the second resistance between a first resistance value and a second resistance value as a function of the comparison signal.

15. The method of claim 14, wherein switching the second resistance comprises short-circuiting one of two resistances coupled in series between the first node and the second terminal when the comparison signal is de-asserted.

16. An integrated circuit comprising a voltage comparison circuit configured to assert a comparison signal in response to determining that an input voltage exceeds a given threshold voltage, the voltage comparison circuit comprising:
a first terminal and a second terminal configured to receive the input voltage;
a third terminal configured to receive a supply voltage;
a measurement circuit configured to generate a measurement signal indicative of the input voltage, wherein the measurement circuit comprises a first resistance coupled between the first terminal and a first node, a second resistance coupled between the first node and the second terminal, and an n-channel Field-Effect Transistor (FET) coupled in series with the first resistance between the first terminal and the first node, wherein a gate terminal of the n-channel FET is coupled to a bias voltage source, wherein the measurement signal corresponds to a voltage at the second resistance;
a first NPN bipolar transistor and a second NPN bipolar transistor, each having a collector terminal, an emitter terminal, and a base terminal, wherein the collector terminals of the first NPN bipolar transistor and the second NPN bipolar transistor are coupled to the third terminal, and the base terminals of the first NPN bipolar transistor and the second NPN bipolar transistor are coupled to the first node, wherein an emitter area of the second NPN bipolar transistor is greater than an emitter area of the first NPN bipolar transistor;
a third resistance coupled between the emitter terminal of the first NPN bipolar transistor and the second terminal, and a fourth resistance coupled between the emitter terminal of the second NPN bipolar transistor and the emitter terminal of the first NPN bipolar transistor; and
a comparison circuit configured to determine whether a first current flowing through the collector terminal of the first NPN bipolar transistor is greater than a second current flowing through the collector terminal of the second NPN bipolar transistor, assert the comparison signal in response to determining that the first current is greater than the second current, and de-assert the comparison signal in response to determining that the first current is smaller than the second current.

17. The integrated circuit of claim 16, further comprising a Power Management Unit configured to change operation as a function of the comparison signal.

18. The integrated circuit of claim 16, wherein the gate terminal of the n-channel FET is coupled to the third terminal.

19. The integrated circuit of claim 16, wherein the second resistance is switchable between a first resistance value and a second resistance value as a function of the comparison signal.

20. The integrated circuit of claim 16, wherein the comparison circuit comprises:
a first transistor of a first current mirror coupled between the collector terminal of the first NPN bipolar transistor and the third terminal;
a second transistor of the first current mirror coupled between the collector terminal of the second NPN bipolar transistor and the third terminal; and
a third transistor and a pull-down resistance coupled between the third terminal and the second terminal, wherein a control terminal of the third transistor is coupled to the collector terminal of the first NPN bipolar transistor,
wherein the comparison signal is determined as a function of a voltage at a node between the third transistor and the pull-down resistance.
